(19) United States
(12) Patent Application Publication
(10) Pub. No.: US 2026/0082624 A1
(43) Pub. Date: Mar. 19, 2026

(54) SEMICONDUCTOR DEVICE AND METHOD FOR MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kazuyuki SATO, Nonoichi Ishikawa (JP); Toshifumi Nishiguchi, Hakusan Ishikawa (JP); Tsuyoshi Kachi, Kanazawa Ishikawa (JP); Hiroaki Katou, Nonoichi Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/038,945

(22) Filed: Jan. 28, 2025

(30) Foreign Application Priority Data
Sep. 18, 2024 (JP) 2024-161093

(51) Int. Cl. H10D 30/66; H10D 30/01; H10D 64/00; H10D 64/27; H10D 64/66; H10D 64/68

(52) U.S. Cl. CPC H10D 30/665; H10D 30/0297; H10D 30/668; H10D 64/117; H10D 64/516; H10D 64/661; H10D 64/687; H10D 64/691; H10D 64/693

(57) ABSTRACT

A semiconductor device according to an embodiment includes a first electrode, a second electrode, and a semiconductor layer. The semiconductor layer includes a first conductivity type first semiconductor region, and a second conductivity type second semiconductor region disposed on the first semiconductor region. The semiconductor device further includes: an insulating region having a cavity extending from an upper end in the first direction; a first control electrode disposed in the insulating region so as to face the second semiconductor region in a second direction ; a second control electrode disposed in the insulating region so as to face the first control electrode in the second direction with the cavity interposed between the first control electrode and the second control electrode; and a conductive portion electrically connected to the first electrode, disposed in the insulating region, and having an upper surface at least partially exposed to a bottom of the cavity.

### CROSS-REFERENCE TO RELATED APPLICATIONS

This application is based upon and claims the benefit of priority from Japanese Patent Application No. 2024-161093, filed on Sep., 18, 2024, the entire contents of which are incorporated herein by reference.

### FIELD

Embodiments described herein relate generally to a semiconductor device and a method for manufacturing the semiconductor device.

### BACKGROUND

As one of MOSFETs, a MOSFET including a field plate electrode (also abbreviated as FPMOSFET or FPMOS) is known. Among the FPMOSs, there is known an FP trench MOS in which a gate electrode and a field plate electrode are disposed in an insulating region embedded in a trench of a semiconductor layer.

In the FP trench MOS, the gate electrode and the field plate electrode are separated from each other by an insulating region. Since the insulating region has a large dielectric constant, a capacitance between the gate electrode and the field plate electrode is large. Due to this, performance of a device may be affected, such as an increase in switching loss.

### BRIEF DESCRIPTION OF THE DRAWINGS

FIG. 1 is a cross-sectional view of a semiconductor device according to a first embodiment;

FIG. 2 is an enlarged view of a region A in FIG. 1;

FIG. 3A is a cross-sectional view for explaining a method for manufacturing the semiconductor device according to the first embodiment;

FIG. 3B is a cross-sectional view for explaining the method for manufacturing the semiconductor device according to the first embodiment, subsequent to FIG. 3A;

FIG. 3C is a cross-sectional view for explaining the method for manufacturing the semiconductor device according to the first embodiment, subsequent to FIG. 3B;

FIG. 3D is a cross-sectional view for explaining the method for manufacturing the semiconductor device according to the first embodiment, subsequent to FIG. 3C;

FIG. 3E is a cross-sectional view for explaining the method for manufacturing the semiconductor device according to the first embodiment, subsequent to FIG. 3D;

FIG. 3F is a cross-sectional view for explaining the method for manufacturing the semiconductor device according to the first embodiment, subsequent to FIG. 3E;

FIG. 3G is a cross-sectional view for explaining the method for manufacturing the semiconductor device according to the first embodiment, subsequent to FIG. 3F;

FIG. 3H is a cross-sectional view for explaining the method for manufacturing the semiconductor device according to the first embodiment, subsequent to FIG. 3G;

FIG. 3I is a cross-sectional view for explaining the method for manufacturing the semiconductor device according to the first embodiment, subsequent to FIG. 3H;

FIG. 4 is a cross-sectional view of a semiconductor device according to a second embodiment;

FIG. 5A is a cross-sectional view for explaining a method for manufacturing the semiconductor device according to the second embodiment;

FIG. 5B is a cross-sectional view for explaining the method for manufacturing the semiconductor device according to the second embodiment, subsequent to FIG. 5A;

FIG. 5C is a cross-sectional view for explaining the method for manufacturing the semiconductor device according to the second embodiment, subsequent to FIG. 5B;

FIG. 5D is a cross-sectional view for explaining the method for manufacturing the semiconductor device according to the second embodiment, subsequent to FIG. 5C;

FIG. 5E is a cross-sectional view for explaining the method for manufacturing the semiconductor device according to the second embodiment, subsequent to FIG. 5D; and

FIG. 5F is a cross-sectional view for explaining the method for manufacturing the semiconductor device according to the second embodiment, subsequent to FIG. 5E.

### DETAILED DESCRIPTION

A semiconductor device according to an embodiment includes a first electrode, a second electrode facing the first electrode in a first direction, and a semiconductor layer disposed between the first electrode and the second electrode. The semiconductor layer includes a first conductivity type first semiconductor region electrically connected to the second electrode, and a second conductivity type second semiconductor region disposed on the first semiconductor region. The semiconductor device further includes: an insulating region disposed in the semiconductor layer and having a cavity extending from an upper end in the first direction; a first control electrode disposed in the insulating region so as to face the second semiconductor region in a second direction orthogonal to the first direction; a second control electrode disposed in the insulating region so as to face the first control electrode in the second direction with the cavity interposed between the first control electrode and the second control electrode; and a conductive portion electrically connected to the first electrode, disposed in the insulating region, and having an upper surface at least partially exposed to a bottom of the cavity.

Hereinafter, an embodiment of the present invention will be described with reference to the drawings. The embodiment does not limit the present invention. The drawings are schematic or conceptual, and a ratio between portions and the like are not necessarily the same as actual ones. In the specification and the drawings, elements similar to those previously described are denoted by the same reference numerals, and detailed description thereof is appropriately omitted.

In the following description, notations of n⁺, n, n⁻, p⁺, p, and p⁻ may be used to represent a relative level of an impurity concentration in a semiconductor region. n⁺ indicates that an n-type impurity concentration is relatively higher than n, and n⁻ indicates that the n-type impurity concentration is relatively lower than n. p⁺ indicates that a p-type impurity concentration is relatively higher than p, and p⁻ indicates that the p-type impurity concentration is relatively lower than p. When both a p-type impurity and an n-type impurity are contained in each region, each of these notations represents a relative level of a net impurity concentration after these impurities are compensated for each other. The n-type, n⁺-type, and n⁻-type are examples of the first conductivity type in the claims. The p-type, p⁺-type, and p⁻-type are examples of the second conductivity type in the claims. Note that, in the following description, the n-type and the p-type may be inverted. That is, the first conductivity type may be p-type, and the second conductivity type may be n-type.

Note that an impurity concentration can be measured by, for example, secondary ion mass spectrometry (SIMS). A relative level of the impurity concentration can also be determined from a level of a carrier concentration obtained by, for example, scanning capacitance microscopy (SCM).

In the description of the embodiment, an XYZ orthogonal coordinate system is used. A direction directed from a drain electrode toward an n³¹ -type semiconductor region is defined as a Z direction. Two directions perpendicular to the Z direction and orthogonal to each other are defined as an X direction and a Y direction. For description, a direction directed from the drain electrode toward the n⁻-type semiconductor region is referred to as “upper”, and a direction opposite to “upper” is referred to as “lower”. These directions are based on a relative positional relationship between the drain electrode and the n⁻-type semiconductor region, and are independent of the direction of gravity.

### First Embodiment

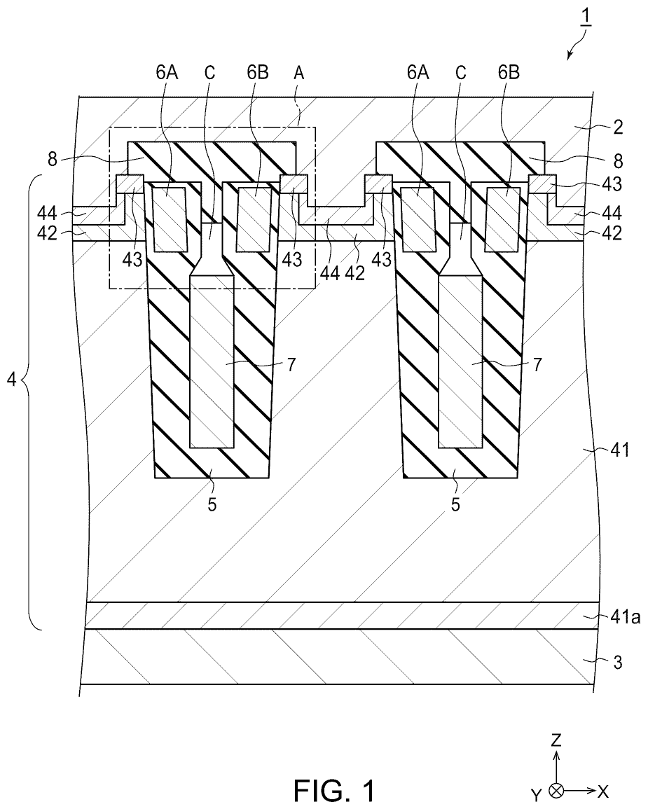

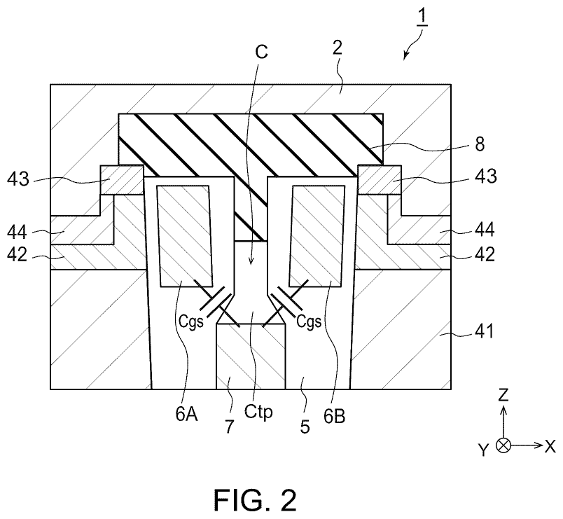

A semiconductor device 1 according to a first embodiment will be described with reference to FIGS. 1 and 2. FIG. 1 is a cross-sectional view of the semiconductor device 1, and FIG. 2 is an enlarged view of a region A in FIG. 1. The semiconductor device 1 is an FP trench MOS in which a gate electrode and a field plate electrode are disposed in an insulating region formed in a trench of a semiconductor layer.

The semiconductor device 1 includes a source electrode 2, a drain electrode 3, a semiconductor layer 4, an insulating region 5, a pair of gate electrodes 6A and 6B, a field plate electrode 7, and an interlayer insulating film 8.

The source electrode 2 is an example of the first electrode in the claims, the drain electrode 3 is an example of the second electrode in the claims. The gate electrode 6A is an example of the first control electrode in the claims, and the gate electrode 6B is an example of the second control electrode in the claims. The field plate electrode 7 is an example of the conductive portion in the claims.

Hereinafter, each component of the semiconductor device 1 will be described.

The source electrode 2 functions as a source electrode of the MOSFET. As described later, the source electrode 2 is electrically connected to a source region 43 and a high concentration region 44 of the semiconductor layer 4 described later. In addition, the source electrode 2 is electrically connected to the field plate electrode 7. The source electrode 2 is made of, for example, copper (Cu), titanium (Ti), tungsten (W), or aluminum (Al).

The drain electrode 3 functions as a drain electrode of the MOSFET. The drain electrode 3 faces the source electrode 2 in the Z-axis direction. The drain electrode 3 is electrically connected to a drain region 41a of the semiconductor layer 4. The drain electrode 3 is made of, for example, copper (Cu), titanium (Ti), titanium nitride (TiN), tungsten (W), or aluminum (Al).

The semiconductor layer 4 includes a drift region 41, the drain region 41a, a base region 42, the source region 43, and the high concentration region 44. The semiconductor layer 4 is disposed between the source electrode 2 and the drain electrode 3. In the present embodiment, the semiconductor layer 4 is made of silicon. Note that the semiconductor layer 4 may be constituted by a semiconductor other than silicon.

The drift region 41 and the drain region 41a are examples of the first semiconductor region in the claims. The base region 42 is an example of the second semiconductor region in the claims, and the source region 43 is an example of the third semiconductor region in the claims. Note that the first semiconductor region in the claims may include both the drift region 41 and the drain region 41a, or may include only one of the drift region 41 and the drain region 41a.

The drift region 41 functions as a drift region of the MOSFET. The drift region 41 is disposed on the drain region 41a. In the present embodiment, the drift region 41 is an n⁻-type semiconductor region. The drift region 41 has an n-type impurity concentration of, for example, 1×10¹⁵ cm⁻³ or more and 2×10¹⁶ cm⁻³ or less.

The drain region 41a functions as a drain region of the MOSFET. The drain region 41a is disposed between the drift region 41 and the drain electrode 3, and is electrically connected to the drain electrode 3 by being in ohmic contact or the like with the drain electrode 3. In the present embodiment, the drain region 41a is an n⁺-type semiconductor region. The drain region 41a has an n-type impurity concentration of, for example, 1×10¹⁸ cm⁻³ or more and 1×10²¹ cm⁻³ or less.

As described above, the n-type semiconductor region including the drift region 41 and the drain region 41a is disposed between the source electrode 2 and the drain electrode 3, and is electrically connected to the drain electrode 3 by being in ohmic contact or the like with the drain electrode 3.

The base region 42 functions as a base region of the MOSFET. The base region 42 is disposed on the drift region 41 and is disposed in the semiconductor layer 4 so as to be sandwiched between the insulating regions 5. In the present embodiment, the base region 42 is a p-type semiconductor region. The base region 42 has a p-type impurity concentration of, for example, 1×10¹⁶ cm⁻³ or more and 1×10²⁰ cm⁻³ or less.

The source region 43 functions as a source region of the MOSFET. The source region 43 is located between the base region 42 and the source electrode 2 as viewed in the Z-axis direction, and is disposed on the base region 42. The source region 43 is electrically connected to the source electrode 2 by being in ohmic contact or the like with the source electrode 2. In the present embodiment, the source region 43 is an n⁺-type semiconductor region. The source region 43 has an n-type impurity concentration of, for example, 1×10¹⁸ cm⁻³ or more and 1×10²² cm⁻³ or less.

The high concentration region 44 is disposed on the base region 42 and is electrically connected to the source electrode 2. In order to reduce recovery loss, the high concentration region 44 is disposed in a portion adjacent to a bottom portion of a contact plug of the source electrode 2. In the present embodiment, the high concentration region 44 is a p⁺-type semiconductor region having an impurity concentration higher than that of the base region 42. The high concentration region 44 has a p-type impurity concentration of, for example, 1×10¹⁸ cm⁻³ or more and 1×10²² cm⁻³ or less. With the high concentration region 44, minority carriers accumulated in the base region 42 are injected into the high concentration region 44, pass through the contact plug, and are discharged to the source electrode 2.

The insulating region 5 is disposed in the semiconductor layer 4. The insulating region 5 is an insulating film that electrically insulates the gate electrodes 6A and 6B from the source electrode 2 and the field plate electrode 7. In the present embodiment, the insulating region 5 is a silicon oxide film. Note that the insulating region 5 may be made of another material such as a silicon nitride film.

As illustrated in FIGS. 1 and 2, the insulating region 5 has a cavity C extending from an upper end toward the drain electrode 3 in the Z-axis direction. The cavity C has a tapered portion Ctp whose length (that is, width) in the X-axis direction increases as it goes from the source electrode 2 toward the drain electrode 3 (that is, from an upper surface to a lower surface of the semiconductor layer 4). The tapered portion Ctp causes an air gap to exist between the gate electrodes 6A and 6B and the field plate electrode 7. As a result, a capacitance Cgs between the gate electrodes 6A and 6B and the field plate electrode 7 can be reduced.

Note that, as illustrated in FIGS. 1 and 2, an opening in an upper portion of the cavity C is closed with an insulating material constituting the interlayer insulating film 8.

The gate electrode 6A is disposed in the insulating region 5 so as to face the base region 42 in the X-axis direction. The gate electrode 6A extends in the Y-axis direction.

The gate electrode 6B is disposed in the insulating region 5 so as to face the gate electrode 6A in the X-axis direction with the cavity C interposed between the gate electrode 6A and the gate electrode 6B. The gate electrode 6B extends in the Y-axis direction.

The gate electrode 6A and the gate electrode 6B are electrically connected to each other. In the present embodiment, the gate electrode 6A and the gate electrode 6B are made of conductive polysilicon or the like containing a p-type or n-type impurity.

The field plate electrode 7 is disposed in the insulating region 5 so as to be located below the gate electrode 6A and the gate electrode 6B. Note that the field plate electrode 7 is not disposed immediately below the gate electrode 6A and the field plate electrode 7 is not disposed immediately below the gate electrode 6B. The field plate electrode 7 is electrically connected to the source electrode 2. The field plate electrode 7 extends in the Y-axis direction.

The field plate electrode 7 is made of conductive polysilicon doped with a p-type or n-type impurity. In the present embodiment, the impurity is phosphorus (P). An impurity concentration is, for example, 1×10¹⁸ cm⁻³ or more and 1×10²² cm⁻³ or less. Note that the impurity may be an element larger than silicon, such as arsenic (As) or antimony (Sb).

As illustrated in FIG. 2, an upper surface of the field plate electrode 7 is exposed to a bottom of the cavity C. This causes an air gap to exist between the gate electrodes 6A and 6B and the field plate electrode 7.

The interlayer insulating film 8 covers the insulating region 5 and a part of the source region 43. In the present embodiment, the interlayer insulating film 8 is made of borophosphosilicate glass (BPSG). Note that the interlayer insulating film 8 may be constituted by another insulating film such as a silicon oxide film, a silicon nitride film, a high dielectric constant film (High-k film), or a low dielectric constant film (Low-k film). The interlayer insulating film 8 can sufficiently ensure insulation between the gate electrodes 6A and 6B and the source electrode 2. Note that the interlayer insulating film 8 may be omitted.

### Operation and Effect

As described above, in the semiconductor device 1 according to the first embodiment, the cavity C extending from an upper end thereof in the Z-axis direction is formed in the insulating region 5, the gate electrodes 6A and 6B are disposed in the insulating region 5 so as to sandwich the cavity C therebetween, and the field plate electrode 7 is disposed in the insulating region 5 such that at least a part of an upper surface thereof is exposed to a bottom of the cavity C. This causes an air gap of the cavity C to exist between the gate electrodes 6A and 6B and the field plate electrode 7, and therefore the capacitance Cgs can be reduced. In the semiconductor device 1, since a cavity of the tapered portion Ctp is formed between the gate electrode 6A and the field plate electrode 7 and between the gate electrode 6B and the field plate electrode 7, the capacitance Cgs can be effectively reduced.

Note that, as illustrated in FIG. 2, an upper end of the field plate electrode 7 may be located near a lower end of the tapered portion Ctp. As a result, the capacitance Cgs can be sufficiently reduced while an effect of improving withstand voltage by the field plate electrode 7 is maintained. That is, when the upper end of the field plate electrode 7 is located above the tapered portion Ctp (on the source electrode 2 side) (when the field plate electrode 7 fills the tapered portion Ctp), there is no air gap between the gate electrodes 6A and 6B and the field plate electrode 7, and therefore there is a risk that the capacitance Cgs cannot be sufficiently reduced. On the other hand, when the upper end of the field plate electrode 7 is located below the tapered portion Ctp (on the drain electrode 3 side), an original function of the field plate electrode 7 (improvement in withstand voltage) may be weakened.

An insulating material of the interlayer insulating film 8 may reach the inside of the tapered portion Ctp from an upper opening of the cavity C. Furthermore, the insulating material may reach the field plate electrode 7. Even in these cases, since an air gap remains in the tapered portion Ctp, the capacitance Cgs can be reduced.

### Method for Manufacturing Semiconductor Device 1

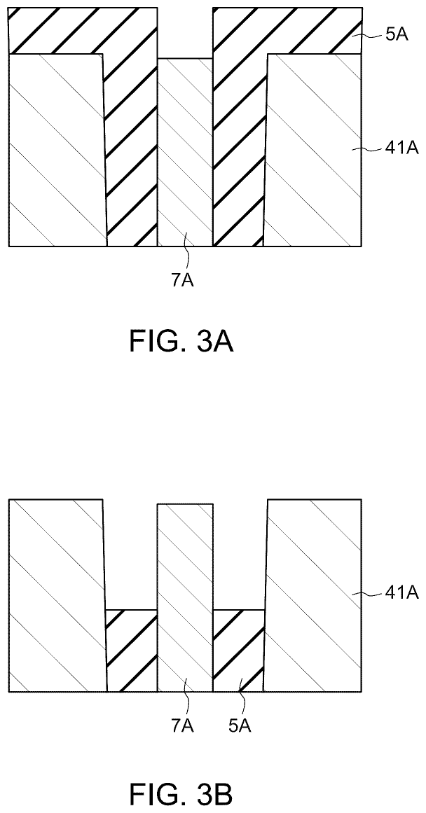

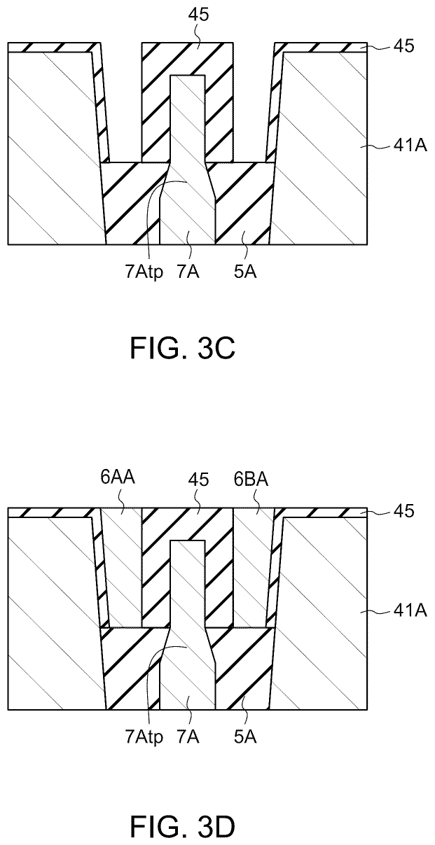

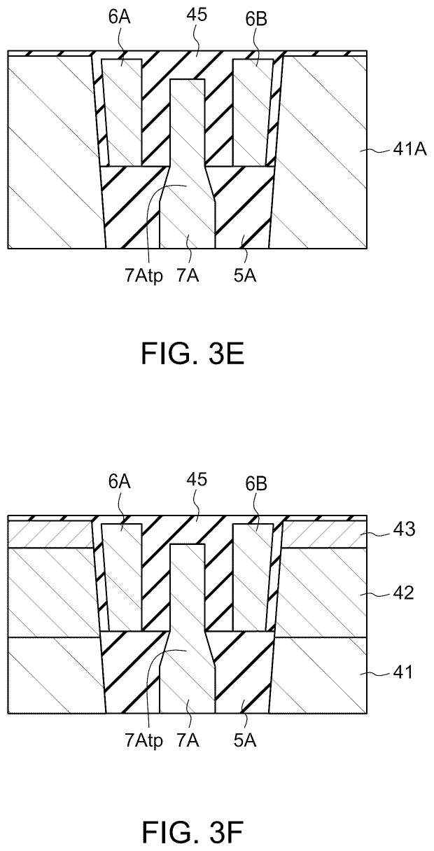

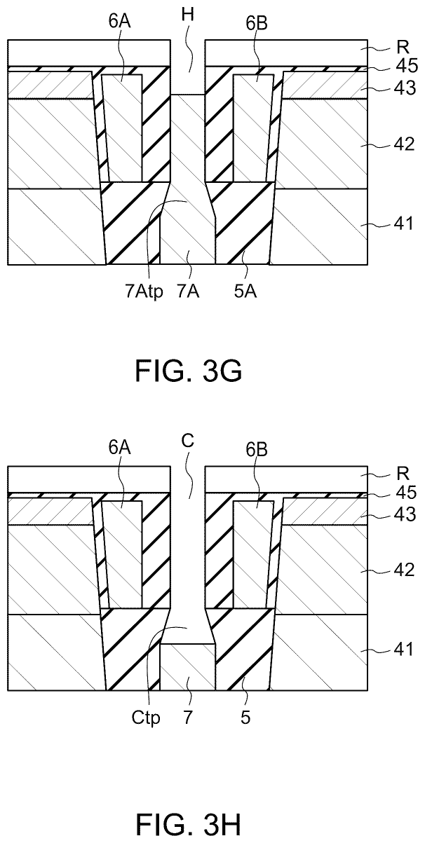

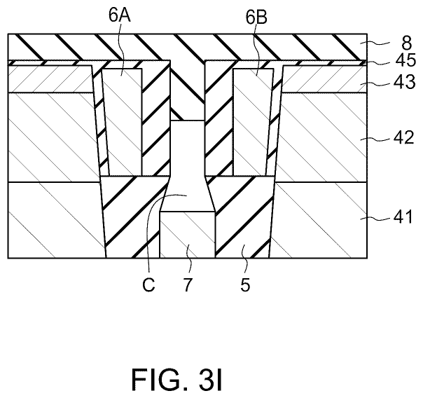

An example of a method for manufacturing the semiconductor device 1 will be described with reference to process cross-sectional views of FIGS. 3A to 3I.

First, a semiconductor layer (silicon wafer or the like) having the n-type semiconductor region 41A is prepared, and a trench is formed on an upper surface of the semiconductor layer. Thereafter, an insulating film (a silicon oxide film in this case) is formed on the upper surface of the semiconductor layer and an inner wall of the trench by performing thermal oxidation to form an insulating region 5A filling the trench. Thereafter, a groove is formed in the insulating region 5A by performing chemical dry etching (CDE).

Next, as illustrated in FIG. 3A, polysilicon is deposited in the above groove by chemical vapor deposition (CVD) or the like. Polysilicon contains an impurity such as phosphorus or arsenic. Thereafter, excessive polysilicon is etched back by performing CDE to form a conductive portion 7A.

Next, as illustrated in FIG. 3B, a part of the insulating region 5A is selectively removed by performing wet etching to expose an upper portion of the conductive portion 7A.

Next, as illustrated in FIG. 3C, an insulating film 45 is formed on the upper surface of the semiconductor layer, the inner wall of the trench, and the exposed conductive portion 7A by performing thermal oxidation. Specifically, a first insulating film is formed on one inner wall (left inner wall) of the trench, a second insulating film is formed on the other inner wall (right inner wall) of the trench, and a third insulating film is formed on the exposed conductive portion.

Since the conductive portion 7A contains an impurity such as phosphorus, the conductive portion 7A is more easily oxidized (amplified oxidation) than the semiconductor region 41A. Therefore, the third insulating film formed on the conductive portion 7A is thicker than the first and second insulating films formed on the inner walls of the trench. In addition, even in an unexposed portion of the conductive portion 7A, a portion relatively shallow from an upper surface of the insulating region 5A is thermally oxidized. In the conductive portion 7A in the insulating region 5A, a portion close to the upper surface of the insulating region 5A is thermally oxidized to form a thick oxide film. As a result, as illustrated in FIG. 3C, a tapered region 7Atp is automatically formed in the conductive portion 7A.

Next, as illustrated in FIG. 3D, polysilicon is deposited by performing CVD in the groove between the insulating film 45 formed on the inner wall of the trench and the insulating film 45 formed on the conductive portion 7A. Note that a material deposited in the groove is not limited to polysilicon as long as the material has conductivity. Thereafter, a gate conductive portion 6AA and a gate conductive portion 6BA sandwiching the conductive portion 7A therebetween are formed by etching back excessive polysilicon. As described above, in this step, the conductive material is deposited in the groove between the first insulating film and the third insulating film to form a first gate conductive portion, and the conductive material is deposited in the groove between the second insulating film and the third insulating film to form a second gate conductive portion.

Next, as illustrated in FIG. 3E, upper portions of the gate conductive portions 6AA and 6BA are oxidized by performing thermal oxidation (buffer oxidation) to be integrated with the insulating film 45. Portions of the gate conductive portions 6AA and 6BA that have not been oxidized serve as the gate electrodes 6A and 6B. The gate electrodes 6A and 6B are formed so as to sandwich the conductive portion 7A therebetween. Thereafter, etching is performed to thin the insulating film 45 on an upper surface of the semiconductor layer.

Next, as illustrated in FIG. 3F, ions of a p-type impurity are implanted to the semiconductor region 41A to form the base region 42. Thereafter, ions of an n-type impurity are implanted to the base region 42 to form the source region 43 in an upper portion of the base region 42. A portion of the semiconductor region 41A where the base region 42 or the source region 43 has not been formed serves as the drift region 41.

Next, as illustrated in FIG. 3G, a resist film R having an opening at a position corresponding to the conductive portion 7A is formed on the insulating film 45. The opening of the resist film R is formed by photolithography. Thereafter, the insulating film 45 immediately above the conductive portion 7A is removed by performing reactive ion etching (RIE) using the resist film R as a mask to form a hole H in which the conductive portion 7A is exposed to a bottom surface thereof.

Next, as illustrated in FIG. 3H, the conductive portion 7A exposed to the hole H is selectively removed by performing etching such as CDE. Specifically, the conductive portion 7A is removed until an upper surface thereof is located below the gate electrodes 6A and 6B. As a result, the field plate electrode 7 is formed, and the cavity C is formed. The tapered region 7Atp is removed to form the tapered portion Ctp. A portion of the conductive portion 7A remaining without being removed in this step serves as the field plate electrode 7. Note that, by grasping an etching rate in advance, the upper surface of the field plate electrode 7 may be caused to be located near a lower end of the tapered portion Ctp.

Next, as illustrated in FIG. 3I, the resist film R is removed, and then the interlayer insulating film 8 is formed on the insulating film 45 by performing CVD. Note that, in this step, there is a possibility that the interlayer insulating film 8 (a silicon oxide film in this case) enters the cavity C. However, since the tapered portion Ctp is not filled with an insulating material, an air gap remains at least in the tapered portion Ctp.

Thereafter, although not illustrated, a contact hole penetrating the interlayer insulating film 8 and the source region 43 and reaching the base region 42 is formed, and ions of a p-type impurity are implanted to the contact hole to form the high concentration region 44. Thereafter, a metal material is deposited so as to fill the contact hole and embed the interlayer insulating film 8 by performing CVD to form the source electrode 2. Thereafter, a metal material is deposited on a lower surface of the semiconductor layer to form the drain electrode 3.

### Second Embodiment

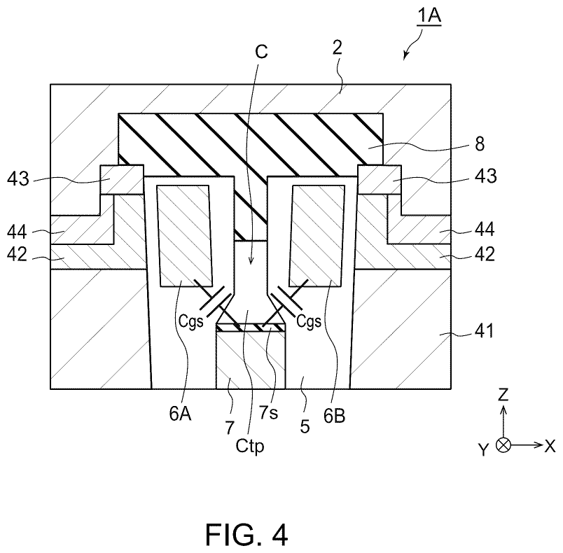

A semiconductor device 1A according to a second embodiment will be described with reference to FIG. 4. In the semiconductor device 1A, an insulating film 7s which is an etching stopper film is disposed on an upper surface of a field plate electrode 7. Hereinafter, the second embodiment will be described focusing on a difference from the first embodiment.

The semiconductor device 1A of the present embodiment includes a source electrode 2, a drain electrode 3, a semiconductor layer 4, an insulating region 5, a pair of gate electrodes 6A and 6B, a field plate electrode 7, and an interlayer insulating film 8.

An upper surface of the field plate electrode 7 is covered with the insulating film 7s. In the present embodiment, the insulating film 7s is a silicon oxide film. Note that a material of the insulating film 7s is not limited to silicon oxide, and may be any material as long as it functions as an etching stopper.

As in the first embodiment, the insulating region 5 of the semiconductor device 1A has a cavity C extending from an upper end toward the drain electrode 3 in the Z-axis direction and having a tapered portion Ctp. As a result, according to the present embodiment, the same effects as those of the first embodiment can be obtained. That is, since an air gap exists between the gate electrodes 6A and 6B and the field plate electrode 7, a capacitance Cgs between the gate electrodes 6A and 6B and the field plate electrode 7 can be reduced.

### Method for Manufacturing Semiconductor Device 1A

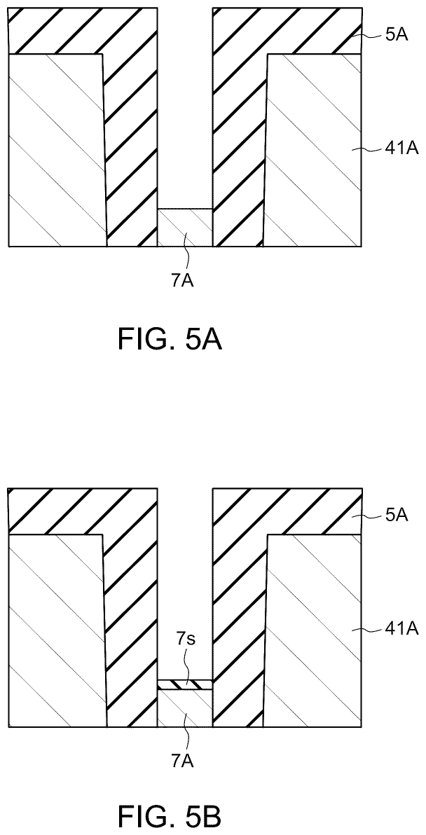

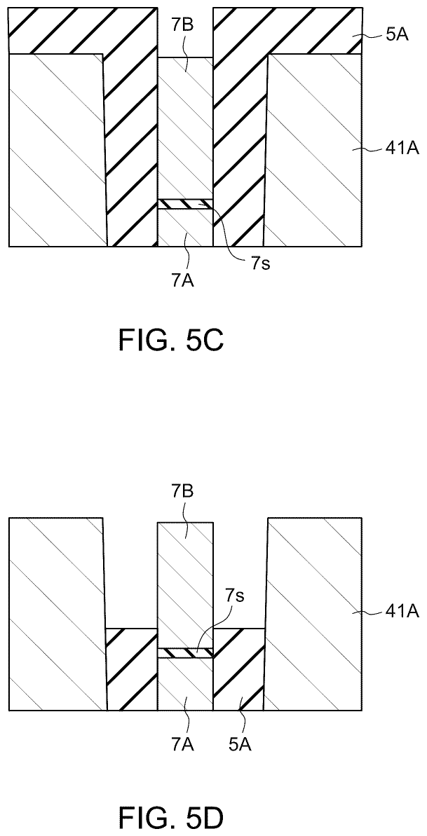

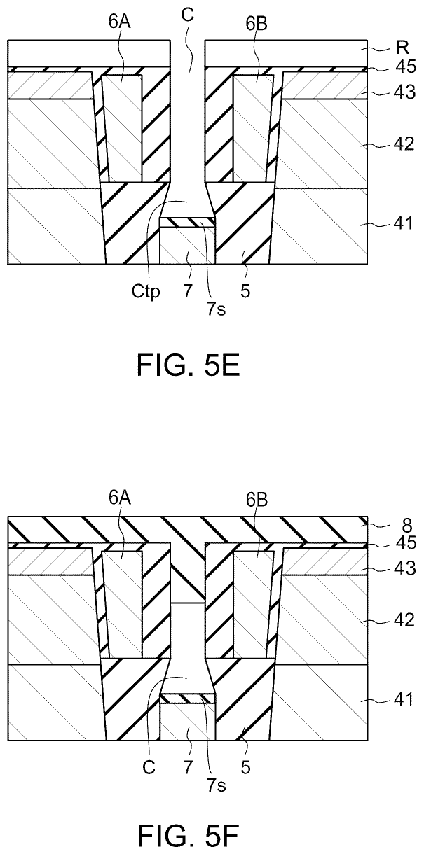

An example of a method for manufacturing the semiconductor device 1A will be described with reference to process cross-sectional views of FIGS. 5A to 5F.

First, a semiconductor layer (silicon wafer or the like) having an n-type semiconductor region 41A is prepared, and a trench is formed on an upper surface of the semiconductor layer. Thereafter, an insulating region 5A (a silicon oxide film in this case) is formed on the upper surface of the semiconductor layer and an inner wall of the trench by performing thermal oxidation. Thereafter, a groove is formed in the insulating region 5A filling the trench by performing CDE.

Next, as illustrated in FIG. 5A, polysilicon is deposited in the above groove by performing CVD. Polysilicon contains an impurity such as phosphorus or arsenic. Thereafter, excessive polysilicon is etched back by performing CDE to form a conductive portion 7A. At this time, polysilicon in the groove is removed more (deeper) than in the case described in the first embodiment. Specifically, polysilicon is removed up to a region below a region where the gate electrodes 6A and 6B are to be formed. The conductive portion 7A serves as the field plate electrode 7 of the semiconductor device 1A.

Next, as illustrated in FIG. 5B, the insulating film 7s (etching stopper film) is formed on an upper surface of the conductive portion 7A by performing thermal oxidation. Here, the insulating film 7s is made of silicon oxide.

Next, polysilicon is deposited on the insulating film 7s by performing CVD. Polysilicon contains an impurity such as phosphorus or arsenic. Thereafter, as illustrated in FIG. 5C, excessive polysilicon is etched back by performing CDE to form a conductive portion 7B. The conductive portion 7B is an example of the second conductive portion in the claims.

Next, as illustrated in FIG. 5D, a part of the insulating region 5A is selectively removed by performing wet etching to expose the conductive portion 7B. Note that, at this time, an upper surface of the insulating region 5A is caused to be located above the insulating film 7s. Thereafter, the steps described with reference to FIGS. 3C to 3G in the first embodiment are performed.

Next, as illustrated in FIG. 5E, the conductive portion 7B exposed to the hole H is selectively removed by performing etching such as CDE. At this time, since the insulating film 7s functions as an etching stopper, the conductive portion 7A is not removed. Through this step, the cavity C having the tapered portion Ctp is formed.

Next, as illustrated in FIG. 5F, the resist film R is removed, and then the interlayer insulating film 8 is formed on the insulating film 45 by performing CVD. Thereafter, as in the case of the first embodiment, a contact hole is formed to form the high concentration region 44. Thereafter, the source electrode 2 and the drain electrode 3 are formed.

Through the above steps, the semiconductor device 1A according to the second embodiment is manufactured. According to the present embodiment, by covering the upper surface of the conductive portion 7A with the insulating film 7s, it is possible to prevent the conductive portion 7A from being removed in the etching step of forming the cavity C. As a result, the height of the upper surface of the field plate electrode 7 can be easily controlled. As a result, for example, as illustrated in FIG. 4, the upper end of the field plate electrode 7 is easily caused to be located near a lower end of the tapered portion Ctp. As a result, it is possible to provide the semiconductor device 1A capable of sufficiently reducing the capacitance Cgs while maintaining an effect of improving withstand voltage by the field plate electrode 7.

According to at least one embodiment described above, the capacitance between the gate electrode and the field plate electrode can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first electrode;
a second electrode facing the first electrode in a first direction;
a semiconductor layer disposed between the first electrode and the second electrode and including a first conductivity type first semiconductor region electrically connected to the second electrode, and a second conductivity type second semiconductor region disposed on the first semiconductor region;
an insulating region disposed in the semiconductor layer and having a cavity extending from an upper end in the first direction;
a first control electrode disposed in the insulating region so as to face the second semiconductor region in a second direction orthogonal to the first direction;
a second control electrode disposed in the insulating region so as to face the first control electrode in the second direction with the cavity interposed between the first control electrode and the second control electrode; and
a conductive portion electrically connected to the first electrode, disposed in the insulating region, and having an upper surface at least partially exposed to a bottom of the cavity.

2. The semiconductor device according to claim 1, wherein the cavity has a tapered portion whose length in the second direction increases as it goes from the first electrode toward the second electrode.

3. The semiconductor device according to claim 2, wherein an upper end of the conductive portion is located near a lower end of the tapered portion.

4. The semiconductor device according to claim 2, wherein the conductive portion is not disposed immediately below the first control electrode and the conductive portion is not disposed immediately below the second control electrode.

5. The semiconductor device according to claim 2, wherein the conductive portion is made of polysilicon containing phosphorus as an impurity, and the insulating region is made of silicon oxide or silicon nitride.

6. The semiconductor device according to claim 1, wherein an upper surface of the conductive portion is covered with an insulating film.

7. The semiconductor device according to claim 6, wherein the conductive portion is made of polysilicon, and the insulating film is made of silicon oxide or silicon nitride.

8. The semiconductor device according to claim 6, wherein the conductive portion is not disposed immediately below the first control electrode and the conductive portion is not disposed immediately below the second control electrode.

9. The semiconductor device according to claim 6, wherein the conductive portion is made of polysilicon containing phosphorus as an impurity, and the insulating region is made of silicon oxide or silicon nitride.

10. The semiconductor device according to claim 1, wherein the conductive portion is not disposed immediately below the first control electrode and the conductive portion is not disposed immediately below the second control electrode.

11. The semiconductor device according to claim 1, wherein the conductive portion is made of polysilicon containing phosphorus as an impurity, and the insulating region is made of silicon oxide or silicon nitride.

12. The semiconductor device according to claim 1, further comprising an interlayer insulating film that covers the insulating region, wherein
an opening in an upper portion of the cavity is closed with an insulating material constituting the interlayer insulating film.

13. The semiconductor device according to claim 12, wherein the insulating material of the interlayer insulating film reaches an inside of a tapered portion from the opening in the upper portion of the cavity.

14. The semiconductor device according to claim 1, further comprising a first conductivity type third semiconductor region disposed on the second semiconductor region and electrically connected to the first electrode.

15. The semiconductor device according to claim 1, further comprising a second conductivity type high concentration region disposed on the second semiconductor region and in a portion adjacent to a bottom portion of a contact plug of the first electrode and electrically connected to the first electrode.

16. The semiconductor device according to claim 1, wherein the first conductivity type is n-type, and the second conductivity type is p-type.

17. A method for manufacturing a semiconductor device, comprising:
forming a trench on an upper surface of a semiconductor layer having a first conductivity type semiconductor region;
forming an insulating region filling the trench;
forming a groove in the insulating region;
depositing a conductive material in the groove to form a conductive portion;
removing a part of the insulating region to expose an upper portion of the conductive portion;
forming a first insulating film on one inner wall of the trench, a second insulating film on the other inner wall of the trench, and a third insulating film on the exposed conductive portion;
depositing a conductive material in a groove between the first insulating film and the third insulating film to form a first gate conductive portion;
depositing a conductive material in a groove between the second insulating film and the third insulating film to form a second gate conductive portion;
implanting ions of a second conductivity type impurity to the semiconductor region to form a base region;
implanting ions of a first conductivity type impurity to the base region to form a source region in an upper portion of the base region; and
removing the conductive portion until an upper surface of the conductive portion is located below the first and second gate conductive portions to form a cavity extending from an upper end in a thickness direction of the semiconductor layer and having a tapered portion whose width increases as it goes from an upper surface toward a lower surface of the semiconductor layer.

18. A method for manufacturing a semiconductor device, comprising:
forming a trench on an upper surface of a semiconductor layer having a first conductivity type semiconductor region;
forming an insulating region filling the trench;
forming a groove in the insulating region;
depositing a conductive material in the groove and removing the conductive material up to a region below a region where a gate electrode is to be formed to form a conductive portion;
forming an etching stopper film on the conductive portion;
forming a second conductive portion on the etching stopper film;
removing a part of the insulating region to expose the second conductive portion;
forming a first insulating film on one inner wall of the trench, a second insulating film on the other inner wall of the trench, and a third insulating film on the exposed second conductive portion;
depositing a conductive material in a groove between the first insulating film and the third insulating film to form a first gate conductive portion;
depositing a conductive material in a groove between the second insulating film and the third insulating film to form a second gate conductive portion;
implanting ions of a second conductivity type impurity to the semiconductor region to form a base region;
implanting ions of a first conductivity type impurity to the base region to form a source region in an upper portion of the base region; and
removing the second conductive portion formed on the etching stopper film to form a cavity extending from an upper end in a thickness direction of the semiconductor layer and having a tapered portion whose width increases as it goes from an upper surface toward a lower surface of the semiconductor layer.
